(19) United States
(12) Patent Application Publication
(10) Pub. No.: US 2011/0045646 A1
(43) Pub. Date: Feb. 24, 2011

(54) SELECTIVE DEPOSITION OF SIGE LAYERS FROM SINGLE SOURCE OF SI-GE HYDRIDES

(75) Inventors: John Kouvetakis, Mesa, AZ (US); Yan-Yan Fang, Tempe, AZ (US)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: Arizona Board of Regents, Scottsdale, AZ (US)

(21) Appl. No.: 12/866,945

(22) PCT Filed: Mar. 27, 2009
(86) PCT No.: PCT/US09/38568

§ 371 Date: Nov. 10, 2010

Related U.S. Application Data
(60) Provisional application No. 61/041,656, filed on Apr. 2, 2008.

(51) Int. Cl. H01L 21/20; H01L 21/336

(52) U.S. Cl. 438/285; 438/478; 257/E21.09; 257/E21.409

(57) ABSTRACT

Single-source silyl-germanes hydrides can be used to deposit Gei_xSix seamlessly, conformally and selectively in the “source/drain” regions of prototypical transistors, leading to potentially significant performance gains derived from mobility enhancement, and applications in optoelectronics. Low-temperature heteroepitaxy (300-430° C.) produces monocrystalline microstructures, smooth and continuous surface morphologies and low defect densities. Strain engineering can be achieved by incorporating the entire SiGe content of precursors into the film.

### CROSS REFERENCE

This application claims priority to U.S. Provisional Patent Application Ser. No. 61/041,656 filed Apr. 2, 2008, incorporated by reference herein in its entirety.

### STATEMENT OF GOVERNMENT INTEREST

The invention described herein was made in part with government support under grant number FA9550-06-0100442, awarded by the Air Force Office of Scientific Research under the Multidisciplinary Research Program of the University Research Initiative (MURI). The United States Government has certain rights in the invention.

### FIELD OF THE INVENTION

The invention generally relates to the preparation of SiGe layers on solid supports. In particular, the invention relates to methods for the selective deposition of SiGe layers on supports having a surface comprising at least two different materials.

### BACKGROUND OF THE INVENTION

Fully strained Si₁₋ₓGeₓ alloys with x=0.20-0.30 grown by selective epitaxy in the source and drain (S/D) of a PMOS transistor compress the Si-channel to significantly increase the hole mobility and thus the speed of the device (Wang et al., Japan J. Appl. Phys 2007, 46(4B), 2062-2066; Ang et al., Appl. Phys. Lett. 2005, 86, 093102; and Ang et al., IEEE Electron Device Lett. 2007, 28, 609). Related Si₁₋ₓGeₓ stressors with Ge-rich compositions, x≧0.50, are of particular interest because they are expected to produce disruptive improvements in the saturation/drive currents compared to conventional Si transistors with similar structural parameters (Murthy et al., US Patent Application Publication No. 2006/0131665A1). Here the larger lattice spacing of the alloy induces a tetragonal compressive strain in the active Si areas with a magnitude proportional to the Ge concentration in the stressor. At the current upper limit of ˜25-30 at. % Ge this leads to a ˜20% increase in the saturation current. Any further improvements will require higher Ge concentrations in the stressor alloy to achieve the unprecedented compressive strains associated with the larger Si₁₋ₓGeₓ/Si lattice mismatches within the device structure.

Conventional selective growth of Si₁₋ₓGeₓ alloys is achieved using high temperature reactions of chlorosilanes, germane and elemental Cl₂ which typically do not yield films with suitable morphology and microstructure in the high Ge concentration range. For example, selective growth of Si₁₋ₓGeₓ alloys has been achieved using high temperature reactions of chlorosilanes, germane and elemental Cl₂. However, the complexity of the associated multicomponent reactions and the presence of corrosive Cl₂ call for alternative approaches to selective growth. This need is particularly acute in the high Ge-concentration range, for which the chlorosilane route does not yield films with suitable morphology and microstructure. Furthermore, for high Ge content the conventional processes lead to high dislocation densities, non-uniformities in strain, lack of compositional control, and reduced film thickness, all of which ultimately can degrade the quality and performance of the stressor material thereby limiting the practical usefulness of this approach.

Therefore, there exists a need in the art for methods for the selective deposition of SiGe materials, and in particular, high Ge content SiGe materials on substrates which avoid the issues described above.

### SUMMARY OF THE INVENTION

The instant invention exploits unexpected and unique growth properties of Si—Ge hydride compounds to selectively deposit SiGe layers, for example, as strained-layered heterostructures of Ge-rich semiconductors in the source-drain regions of PMOS structures. Particularly, the methods of the present invention can achieve high strain states in SiGe layers that are typically much thicker than the nominal equilibrium critical thicknesses.

Accordingly, in one aspect, the invention provides methods for the selective deposition of a Si₁₋ₓGeₓ layer comprising contacting a substrate having a surface layer comprising at least two portions, wherein a first portion of the surface layer comprises a semiconductor surface layer and a second portion of the surface layer comprises an oxide, nitride, or oxynitride surface layer; with a gaseous precursor comprising a compound of the molecular formula, Si_{y}Ge_{z}Hₐ, wherein y is 1, 2, 3, or 4; z is 1, 2, 3, or 4; and a is 2(y+z+1); provided that the sum of y and z is less than or equal to 5; and z is greater than or equal to y; under conditions sufficient to selectively deposit a Si₁₋ₓGeₓ layer, having a predetermined thickness and at a predetermined rate, over only the first portion of the surface, wherein x is greater than about 0.45.

In a second aspect, the invention provides methods for growing a fully compressively strained SiₓGe₁₋ₓ layer on a substrate comprising, contacting a semiconductor substrate with a gaseous precursor comprising a compound of the molecular formula, Si_{y}Ge_{z}Hₐ, wherein y is 1, 2, 3, or 4; z is 1, 2, 3, or 4; a is 2(y+z+1); provided that the sum of y and z is less than or equal to 5; and z is greater than or equal to y; under conditions sufficient to deposit a fully compressively strained Si₁₋ₓGeₓ layer, having a thickness, at a predetermined rate; and wherein x is greater than about 0.45.

### BRIEF DESCRIPTION OF THE DRAWINGS

FIG. 1(a) XRD (224) reciprocal space maps of SiGe/Si indicating that the Si_{0.50}Ge_{0.50} epilayer is fully strained to the substrate. Note that the SiGe (224) peak falls directly below that of the Si counterpart indicating lattice matching in the plane of growth.

FIG. 1(b) is a high resolution micrograph showing a perfectly commensurate SiGe/Si interface.

FIG. 1(c) is a bright field micrograph of the entire SiGe layer with a 60 nm thickness showing a flat surface and a film microstructure devoid of dislocations, consistent with a fully commensurate material exhibiting 2% compressive strain.

FIG. 2(a) is a XTEM micrograph of SiGe₃ trenches grown selectively in the “source” and “drain” areas of a device via deposition of HSi(GeH₃)₃ at 350° C.

FIG. 2(b) is a XTEM micrograph showing selective growth of a 70 nm Si_{0.25}Ge_{0.75} film. The enlarged view reveals the absence of any deposition on nitride spacers or on the polysilicon gate hardmask.

FIG. 2(c) is a XTEM micrograph of an essentially perfectly epitaxial Si_{0.25}Ge_{0.75}/Si interface.

FIG. 3 is a graph comparing the measured compressive strain as a function of thickness for Si_{0.50}Ge_{0.50} films grown on blank Si substrates using the GeH₃SiH₃ precursor at 430° C.; solid squares: strain observed in Si_{0.50}Ge_{0.50} alloys grown selectively on patterned substrates; circles: Si_{0.50}Ge_{0.50} grown by MBE at 500° C. by Bean et al; solid line: the equilibrium compressive strain as a function of thickness for Si_{0.50}Ge_{0.50} alloys on Si; dotted and dash-dotted lines were computed from the modified kinetic theory discussed in the text for growth temperatures of 430° C. and 50° C., respectively. The inset shows (empty squares) the compressive strain as a function of thickness for Si_{0.25}Ge_{0.75} films grown on blank Si substrates using the (GeH₃)₃SiH precursor at 330° C. The solid line is the predicted strain from the equilibrium theory, and the dotted line is a fit with the modified kinetic theory with parameters as discussed in the text.

### DETAILED DESCRIPTION OF THE INVENTION

According to the methods of the invention, the Si₁₋ₓGeₓ layer can be selectively deposited by any method known to those skilled in the art utilizing a gas source comprising a compound of the molecular formula, Si_{y}Ge_{z}Hₐ (I), wherein y is 1, 2, 3, or 4; z is 1, 2, 3, or 4; a is 2(y+z+1); provided that the sum of y and z is less than or equal to 5, and z is greater than or equal to y. Preferably, the Si₁₋ₓGeₓ layer is selectively deposited wherein x is greater than about 0.45. More preferably, x is about 0.45-0.95. In certain embodiments, x is about 0.45-0.55. In certain other embodiments, x is about 0.70-0.80.

In one embodiment, the present invention provides methods for selectively depositing a Si—Ge material on a substrate in a reaction chamber, comprising introducing into the chamber a gaseous precursor comprising or consisting of one or more compounds according to formula (I), under conditions whereby a layer comprising a SiGe material is selectively formed on the substrate.

In another embodiment, the present invention provides methods for selectively depositing an epitaxial SiGe layer on a substrate, comprising introducing near a surface of the substrate a gaseous precursor comprising or consisting of one or more compounds according to formula (I), and dehydrogenating the precursor under conditions whereby epitaxial Si—Ge is selectively formed on only the first portion of the substrate surface.

In any embodiment, the substrate can be any substrate suitable for semiconductor or flat panel display use, having a surface layer comprising at least two portions, wherein at least a first portion of the surface layer comprises a semiconductor surface layer and a second portion of the surface layer comprises an oxide, nitride, or oxynitride surface layer. It has been unexpectedly discovered that, upon exposure of such substrates to a vapor comprising a compound of formula (I), the Si—Ge layer formed thereon selectively deposits only on the first portion of the substrate, wherein the second substrate is essentially free of the Si—Ge layer. “Essentially free” as used herein means that the alloy is not detectable on the second portion of the substrate as measured by microraman spectroscopy at a resolution of 1 μm, according to methods known to those skilled in the art.

As used herein, a “semiconductor surface layer” means a layer of an elemental or alloy material having semiconducting properties that is part of or formed on top of a substrate. Examples of materials having semiconducting properties include, but are not limited to, Si, Ge, SiGe, and Si₁₋ₓCₓ, SiGeC, GeSn, SiGeSn.

As used herein, an “oxide, nitride, or oxynitride surface layer” means a layer of an oxide, nitride, or oxynitride chemical compound (i.e., not a semiconductor surface layer as defined herein) that is part of or formed on top of a substrate. Such oxide, nitride, or oxynitride chemical compounds can be semiconducting, or insulating. Examples of oxide, nitride, or oxynitride chemical compounds include, but are not limited to, SiO₂, GeON, Si₃N₄, and SiON.

For example, the first portion of the substrate layer can comprise silicon, germanium, silicon on insulator, Ge:Sn alloys, Si:Ge alloys, Si:C alloys, elemental Si, or elemental Ge. The second portion of the substrate surface can comprise oxide, nitride, or oxynitride surface layer, for example, SiO₂, sapphire, quartz, GeO₂, Si₃N₄, SiON, Ge₃N₄, GeON, Ta₂O₅, ZrO₂, and TiO₂. In a preferred embodiment, the first portion of the substrate comprises Si(100) or Si(111). More preferably, the first portion of the substrate comprises Si(100), such as, but not limited to, n-doped or p-doped Si(100).

Embodiments of the gaseous precursors are as described above for previous aspects of the invention. For example, the methods may further comprise adding a dopant on the substrate, including but not limited to dopants such as boron, phosphorous, arsenic, and antimony. These embodiments are especially preferred for semiconductor substrates used as active devices. Inclusion of such dopants into the semiconductor substrates can be carried out by standard methods in the art. For example, dopants can be included according to the methods described in U.S. Pat. No. 7,238,596, which is hereby incorporated by reference.

“Doping” as used herein refers to the process of intentionally introducing impurities into an intrinsic semiconductor in order to change its electrical properties. Low doping levels are typically on the order of 1 dopant atom for about every 10⁸⁻⁹ atoms; high doping levels are typically on the order of 1 dopant atom in 10⁴ atoms.

In another embodiment, the methods comprise adding varying quantities of carbon or tin to the semiconductor substrate. Inclusion of carbon or tin into the semiconductor substrates can be carried out by standard methods in the art. The carbon can be used to reduce the mobility of the dopants, such as boron, in the structure. Incorporation of Sn can yield materials with novel optical properties such as direct emission and absorption leading to the formation of Si-based lasers and high sensitivity infrared photodetectors.

As demonstrated herein, the silicon-germanium hydrides can be used to deposit device quality layers on substrates that display homogeneous compositional and strain profiles, low threading dislocation densities and atomically planar (i.e., flat) surfaces.

In a preferred embodiment, the gaseous precursor can be introduced in substantially pure form. In a further preferred embodiment, the gaseous precursor can be introduced as a single gas source.

In another embodiment, the gaseous precursor can be introduced intermixed with an inert carrier gas. In this embodiment, the inert gas can be, for example, H₂, He, N₂, argon, or mixtures thereof. Preferably, the inert gas is H₂ or N₂.

In these aspects, the gaseous precursor can be deposited by any suitable technique, including but not limited to gas source molecular beam epitaxy, chemical vapor deposition, plasma enhanced chemical vapor deposition, laser assisted chemical vapor deposition, and atomic layer deposition.

In a preferred embodiment, the gaseous precursor is introduced at a temperature of between 300-500° C.; preferably, 300° C. and 450° C., and more preferably between 350° C. and 450° C. or between 300° C. and 350° C. Practical advantages associated with this low temperature/rapid growth process include (i) deposition compatible with preprocessed Si wafers, (ii) selective growth for application in high frequency devices, and (iii) negligible mass segregation of dopants, which is particularly critical for thin layers.

In various further embodiments, the gaseous precursor is introduced at a partial pressure between 10⁻⁸ Torr and 1000 Torr. In one preferred embodiment, the gaseous precursor is introduced at between 10⁻⁸ Torr and 10⁻⁵ Torr (corresponding to UHV vertical furnace technology). In one preferred embodiment, the gaseous precursor is introduced at between 10⁻³ and 10⁻⁷ Torr. In yet another preferred embodiment, the gaseous precursor is introduced at between 10⁻⁸ Torr and 100 Torr, corresponding to LPCVD conditions.

In various further embodiments, the selective depositing is performed at a predetermined rate of greater than about 2.0 nm/min. Preferably, the predetermined rate is about 2.0-10.0 nm/min. Such layers preferably have a predetermined thickness is about 25-300 nm.

Silicon-germanium hydride compounds that are useful according to the invention include any conformational form of the compound, including but not limited n, g, and iso-forms of the compounds, and combinations thereof. Exemplary silicon-germanium hydrides comprise or consist of those compounds listed in Table 1. All Si and Ge atoms in the compounds are tetravalent. Dashed lines represent bonds between Si and Ge atoms in the linear versions. In the isobutane and isopentane-like isomers, the Si and Ge atoms inside the brackets are directly bound to the Si or Ge to the left of the brackets; the Si or Ge in parenthesis outside of the brackets at the far right in some of the compounds are directly bound to the last Si or Ge inside of the brackets.

TABLE 1

| | | |
|---|---|---|
| 3 and 4 metal | | |
| variants: | | |
| (a) Linear | SiH₃—GeH₂—GeH₃ | Si₁Ge₂H₈ |
| | GeH₃—SiH₂—GeH₃ | Si₁Ge₂H₈ |
| | SiH₃—GeH₂—GeH₂—GeH₃ | Si₁Ge₃H₁₀ |
| | GeH₃—SiH₂—GeH₂—GeH₃ | Si₁Ge₂H₁₀ |
| (b) iso-butane-like | SiH[(GeH₃)₃] | Si₁Ge₃H₁₀ |
| | GeH[(GeH₃)₂(SiH₃)] | Si₁Ge₃H₁₀ |
| 5 metal atom | | |
| variants: | | |
| (a) Linear: | GeH₃—GeH₂—GeH₂—GeH₂—SiH₃ | Si₁Ge₄H₁₂ |
| | GeH₃—GeH₂—GeH₂—SiH₂—GeH₃ | Si₁Ge₄H₁₂ |
| | GeH₃—GeH₂—SiH₂—GeH₂—GeH₃ | Si₁Ge₄H₁₂ |
| (b) Iso-pentane-like | GeH[(SiH₃)(GeH₃)(GeH₂)](GeH₃) | Si₁Ge₄H₁₂ |
| | GeH[(GeH₃)₂(GeH₂)](SiH₃) | Si₁Ge₄H₁₂ |
| | GeH[(GeH₃)₂(SiH₂)](GeH₃) | Si₁Ge₄H₁₂ |
| | SiH[(GeH₃)₂(GeH₂)](GeH₃) | Si₁Ge₄H₁₂ |
| | GeH[(GeH₃)₂(SiH₂)](GeH₃) | Si₁Ge₄H₁₂ |
| Neopentane-like | Si[(GeH₃)₄] | Si₁Ge₄H₁₂ |

As noted above, these compounds each include the n or g forms, and stereoisomers thereof.

In one embodiment, the compound of formula (I) comprises the compound wherein y is 1 and z is 1, 2, 3, or 4. Preferably, the compound is of formula (H₃Ge)_{b}SiH_{4-b}, (II), wherein b is 1, 2, 3, or 4.

In another embodiment, the compound of formula (I) comprises the compound wherein y is 2 and z is 2 or 3.

In a preferred embodiment, the silicon germanium hydride is (H₃Ge)₃—SiH. In another preferred embodiment, the silicon germanium hydride is H₃Ge—SiH₃. In yet another preferred embodiment, the silicon germanium hydride is GeH₃SiH₂SiH₂GeH₃. In yet another preferred embodiment, the silicon germanium hydride is GeH₃—SiH₂—GeH₂—GeH₃.

This first aspect also provides compositions comprising combinations of the silicon germanium hydrides according to formula I. Such Si—Ge hydride compounds can be prepared, for example, as described in WO 2007/062096 and WO 2007/062056, each filed 31 May 2007, and each of which are hereby incorporated by reference in their entirety.

In any of the preceding embodiments, the Si—Ge material may be formed on only the first portion of the substrate as a strain-relaxed layer having a planar surface; the composition of the Si—Ge material is substantially uniform; and/or the entire Si and Ge framework of the gaseous precursor is incorporated into the Si—Ge material or epitaxial Si—Ge.

Alternatively, in any of the preceding embodiments, the Si—Ge material may be formed on only the first portion of the substrate as a virtually fully-strained layer having a planar surface; the composition of the Si—Ge material is substantially uniform; and/or the entire Si and Ge framework of the gaseous precursor is incorporated into the Si—Ge material or epitaxial Si—Ge. For example, the Si₁₋ₓGeₓ layer can be compressively strained and/or fully strained. In other embodiments, the Si₁₋ₓGeₓ layer has strain value ranging from about −0.50% to about −2.00%. Preferably, the Si₁₋ₓGeₓ layer has strain value ranging from about −0.65% to about −2.00% or about −0.65% to about −1.75%.

In a second aspect, the invention provides methods for growing a fully compressively strained SiₓGe₁₋ₓ layer on a substrate comprising, contacting a semiconductor substrate with a gaseous precursor comprising a compound of the molecular formula, Si_{y}Ge_{z}Hₐ, wherein y is 1, 2, 3, or 4; z is 1, 2, 3, or 4; a is 2(y+z+1); provided that the sum of y and z is less than or equal to 5; and z is greater than or equal to y; under conditions sufficient to deposit a fully compressively strained Si₁₋ₓGeₓ layer, having a thickness, at a predetermined rate, wherein x is greater than about 0.45.

Preferably, the fully compressively strained SiₓGeᵢ, layer is deposited wherein x is greater than about 0.45. More preferably, x is about 0.45-0.95. In certain embodiments, x is about 0.45-0.55. In certain other embodiments, x is about 0.70-0.80.

In one embodiment, the present invention provides methods for depositing a fully compressively strained SiₓGe₁₋ₓ layer on a substrate in a reaction chamber, comprising introducing into the chamber a gaseous precursor comprising or consisting of one or more compounds according to formula (I), under conditions whereby a layer comprising a fully compressively strained SiₓGe₁₋ₓ layer is selectively formed on the substrate.

In another embodiment, the present invention provides methods for depositing an epitaxial fully compressively strained SiₓGe₁₋ₓ layer on a substrate, comprising introducing near a surface of the substrate a gaseous precursor comprising or consisting of one or more compounds according to formula (I), and dehydrogenating the precursor under conditions whereby epitaxial fully compressively strained SiₓGe₁₋ₓ layer is formed on the substrate.

In any embodiment, the substrate can be any substrate suitable for semiconductor or flat panel display use, having a surface layer comprising a semiconductor material. It has been unexpectedly discovered that exposure of such substrates to a vapor comprising a compound of formula (I) under appropriate growth rates and growth temperatures essentially “traps” metastable epitaxy-stabilized tetragonal structures in layers exhibiting a significant thickness up to at least 60 nm. Preferably, the SiGe layers have a thickness greater than the critical minimum thickness, e.g., about 2 nm. In more preferred embodiments, the SiGe layers have a thickness greater than about 2 nm. In more preferred embodiments, the SiGe layers have a thickness ranging from about 2 nm to about 100 nm, and preferably, from about 2 nm to about 60 nm.

For example, the substrate layer can comprise silicon, germanium, silicon on insulator, Ge:Sn alloys, Si:Ge alloys, Si:C alloys, elemental Si, or elemental Ge. In a preferred embodiment, the first portion of the substrate comprises Si(100) or Si(111). More preferably, the first portion of the substrate comprises Si(100), such as, but not limited to, n-doped or p-doped Si(100).

Alternatively, the substrate can have at least two portions, as described with respect to the first aspect of the invention (supra). In such instances, the fully compressively strained SiGe layer is formed only over the first portion of the substrate, as defined above, and the second portion of the substrate surface is essentially free of the SiGe alloy.

Further, the fully compressively strained SiGe layers formed according to the second aspect of the invention can be doped according to methods described herein.

As demonstrated herein, the silicon-germanium hydrides can be used to deposit device quality layers on substrates that display homogeneous compositional and fully compressively strained profiles, low threading dislocation densities and atomically planar (i.e., flat) surfaces.

In a preferred embodiment, the gaseous precursor can be introduced in substantially pure form. In a further preferred embodiment, the gaseous precursor can be introduced as a single gas source.

In another embodiment, the gaseous precursor can be introduced intermixed with an inert carrier gas. In this embodiment, the inert gas can be, for example, H₂, He, N₂, argon, or mixtures thereof. Preferably, the inert gas is H₂ or N₂.

In these aspects, the gaseous precursor can be deposited by any suitable technique, including but not limited to gas source molecular beam epitaxy, chemical vapor deposition, plasma enhanced chemical vapor deposition, laser assisted chemical vapor deposition, and atomic layer deposition.

In a preferred embodiment, the gaseous precursor is introduced at a temperature of between 300-500° C.; preferably, 300° C. and 450° C., and more preferably between 350° C. and 450° C. or between 300° C. and 350° C. Practical advantages associated with this low temperature/rapid growth process include (i) short deposition times compatible with preprocessed Si wafers, (ii) selective growth for application in high frequency devices, and (iii) negligible mass segregation of dopants, which is particularly critical for thin layers.

In various further embodiments, the gaseous precursor is introduced at a partial pressure between 10⁻⁸ Torr and 1000 Torr. In one preferred embodiment, the gaseous precursor is introduced at between 10⁻⁸ Torr and 10⁻⁵ Torr (corresponding to UHV vertical furnace technology). In one preferred embodiment, the gaseous precursor is introduced at between 10⁻³ and 10⁻⁷ Torr. In yet another preferred embodiment, the gaseous precursor is introduced at between 10⁻⁸ Torr and 100 Torr, corresponding to LPCVD conditions.

In various further embodiments, the selective depositing is performed at a predetermined rate of greater than about 2.0 nm/min. Preferably, the predetermined rate is about 2.0-10.0 nm/min. Such layers preferably have a predetermined thickness is about 25-300 nm.

Silicon-germanium hydride compounds that are useful according to the invention include any conformational form of the compound, including but not limited n, g, and iso-forms of the compounds, and combinations thereof as described above with respect to the first aspect of the invention (supra). Exemplary silicon-germanium hydrides comprise or consist of those compounds listed in Table 1.

In one embodiment, the compound of formula (I) comprises the compound wherein y is 1 and z is 1, 2, 3, or 4. Preferably, the compound is of formula (H₃Ge)_{b}SiH_{4-b}, wherein b is 1, 2, 3, or 4.

In another embodiment, the compound of formula (I) comprises the compound wherein y is 2 and z is 2 or 3.

In a preferred embodiment, the silicon germanium hydride is (GeH₃)₃—SiH. In another preferred embodiment, the silicon germanium hydride is H₃Ge—SiH₃. In yet another preferred embodiment, the silicon germanium hydride is GeH₃SiH₂SiH₂GeH₃. In yet another preferred embodiment, the silicon germanium hydride is GeH₃SiH₂GeH₂GeH₃.

In yet other embodiments, the silicon germanium hydride is (GeH₃)₃SiH or GeH₃SiH₂GeH₂GeH₃, and x is about 0.70 to about 0.80. In another embodiment, the silicon germanium hydride is H₃Ge—SiH₃ or GeH₃SiH₂SiH₂GeH₃, and x is about 0.45 to about 0.55. This second aspect also provides compositions comprising combinations of the silicon germanium hydrides according to formula I.

Applications

According to the preceding methods, pure and stoichiometric Si₁₋ₓGeₓ alloys can be formed seamlessly, conformally and selectively, for example, in the source/drain regions of prototypical device structures. This type of selective area growth is also likely to have additional applications in the integration of microelectronics with optical components (photodiodes) into a single chip.

In one example, the surface layer of a substrate can comprise one or a plurality of transistor architectures, each comprising a gate region, a source region, and a drain region, wherein the first portion of the surface layer comprises the source regions and the drain regions and the second portion of the surface layer comprises the gate region. The transistor architecture can be of the CMOS, NMOS, PMOS, or MOSFET-type, as are familiar to those skilled in the art. Accordingly, the SiGe layers of the invention could be selectively deposited in the source and drain regions while the gate regions are essentially free of the SiGe alloy (at least on the surface thereof).

The gate regions on such substrates can comprise, for example, a metal gate layer formed over a gate dielectric layer. Examples of metal gate layers include, but are not limited to, polysilicon, polycrystalline SiGe, Ta, Ir, W, Mo, TiN, TiSiN, WN, TaN, TaSi, NiSi, or IrO₂. Examples of gate dielectric layers include, but are not limited to, SiO₂, SiON, HfO₂, ZrO₂, La₂O₃, Al₂O₃, or HfAlO. Generally, the gate region can comprise an oxide, nitride, or oxynitride hardmask and/or an oxide, nitride, or oxynitride spacers.

### EXAMPLES

### Example 1

### Growth of Continuous and Strained SiGe with H₃SiGeH₃

Initially, the formation of strained, continuous films on blanket (unpatterned) Si(100) wafers was investigated in order to identify optimal conditions that yield the highest possible strain states for thicknesses comparable with those required in device applications. In the second step this procedure was applied to conduct selective growth of strained layers on a patterned wafer incorporating simple transistor architectures.

The substrates were first sonicated in methanol dried under a stream of purified N₂, and then dipped in concentrated HF (5% by volume) to strip the native oxide from the surface. They were then heated in the growth chamber at ˜350° C. under UHV to desorb any residual volatile surface impurities, and flashed at ˜900° C./10⁻¹° Torr for 1 second to remove remaining oxide contaminants from the surface.

In the blanket growth, H₃SiGeH₃ source readily produced smooth and continuous films at a rate up to 5 nm/min., at 430° C. and 5×10⁻⁵ Torr. Note that the deposition temperature is significantly lower than that (450-475° C.) employed in previous studies to produce relaxed thick films using the same H₃SiGeH₃ precursor. In the present case the growth was conducted on 1 cm² samples in a gas source MBE reactor with a nominal base pressure of 10⁻¹⁰ Torr.

Under these conditions films with thicknesses ranging from 45-200 nm were obtained. A comprehensive characterization of the wafers was performed by Rutherford Backscattering (RBS), Raman, X-Ray Diffraction (XRD), Atomic Force Microscopy (AFM), Cross-Sectional Transmission Electron Microscopy (XTEM), and Spectroscopic Ellipsometry (SE). The results are summarized in Table 1. The data indicate the presence of atomically flat Si—Ge films with single crystalline and compressively strained microstructures.

TABLE 1

| Precursor | h (nm) | a(Å) | c(Å) | x^{XRD} | ε_{\|\|}^{XRD} | x^{RBS} | x^{Raman} | ε_{\|\|}^{Raman} |
|---|---|---|---|---|---|---|---|---|
| H₃SiGeH₃ | 57 | 5.428 | 5.595 | 0.49 | 1.70% | 0.50 | 0.53 | 2.0% |
| H₃SiGeH₃ | 70 | 5.446 | 5.585 | 0.50 | 1.45% | 0.50 | 0.51 | 1.4% |
| H₃SiGeH₃ | 200 | 5.493 | 5.556 | 0.52 | 0.65% | | | — |

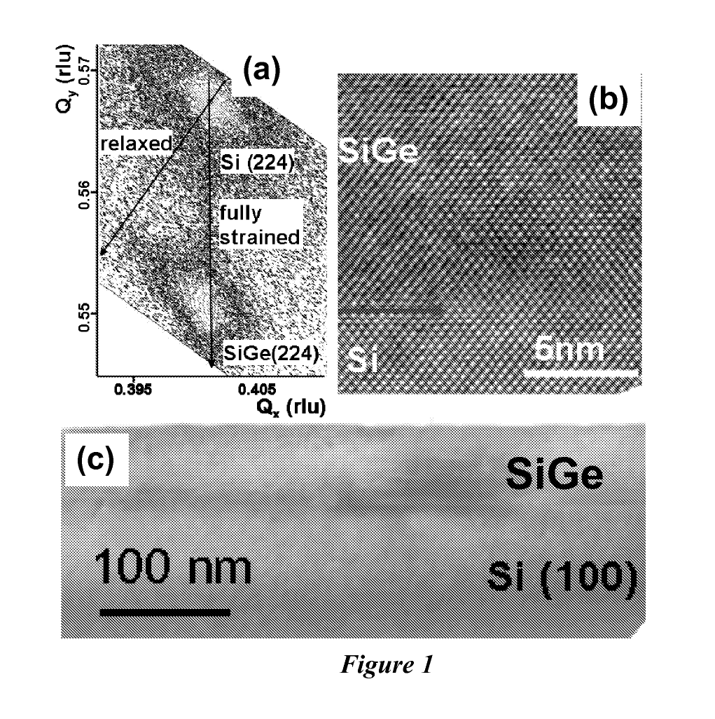

XRD (224) maps for the Si substrate and a 57 nm SiGe film are shown FIG. 1A. The data were referenced for each sample to the corresponding reflections of the Si wafer. The XRD maps were used to determine the in-plane (a_{∥}) and perpendicular (a_{⊥}) lattice constants. The relaxed value a₀(x) was obtained from elasticity theory assuming a tetragonal distortion. This value was used to compute the strain ε_{∥}=(a_{∥}−a₀)/a₀, and to determine the Ge-concentration X^{XRD} from the known compositional dependence of the lattice constant. The SiGe peak is strong and its maximum is located at the fully strained position with respect to Si, consistent with the close matching of the a_{∥SiGe} and a_{∥Si}. Furthermore, the peak is elongated in the vertical direction due to the finite thickness of the film, and appears slightly broadened implying the presence of occasional defects or imperfections within the crystal. Regardless, the overall defect density has to be very small because no threading defects or other type of dislocations are detected in various XTEM and plan view micrographs covering large areas of the layer (FIGS. 1B and 1C).

The RBS channeled spectra reveal a high degree of epitaxial alignment between the film and the underlying Si substrate in all cases. For all samples produced the RBS measurements indicated that the composition was in the range of 53-51% Ge which is close to the stoichiometric 50% Ge concentration in the precursor. The Ge content was independently corroborated by Raman and XRD and was found to be virtually identical to the RBS values. The RBS channeled spectra revealed a high degree of epitaxial alignment between the film and the underlying Si substrate in all cases. The agreement with the value X^{RBS} determined from RBS supports tetragonal deformation.

A protocol was developed for the simultaneous determination of composition and strain using Raman spectroscopy. The Raman spectrum of a Si₁₋ₓGeₓ alloy displays three prominent peaks assigned to Si—Si, Si—Ge, and Ge—Ge vibrations. The compositional dependence of the peaks is known, and the strain shifts are assumed to be of the form bε_{∥} where ε_{∥}=(a_{∥}−a₀)/a₀. Values of b_{Si-Si}=−958 cm⁻¹, b_{Si-Ge}=−575 cm⁻¹, and b_{Ge-Ge}=−415 cm⁻¹ were used. There is very good agreement between the three techniques and that the experimental composition is very close to the precursor stoichiometry.

Collectively the data reveal that the degree of strain in a film is inversely related to its thickness. For example, the 200, 70 and 55 nm thick samples exhibited strain values of −0.65%, −1.45% and −1.75%, respectively. The XRD data show that the in-plane lattice constant of the 55 nm thick sample is 5.428 Å—essentially identical to that of relaxed Si-indicating that this film is virtually fully strained. Furthermore the strain of 2.0% obtained from Raman analysis corresponds to the exact value of the intrinsic strain for this particular film stoichiometry.

These results indicate that the extremely low growth temperature and the relatively high growth rate “lock-in” remarkably metastable strain states in a systematic and controlled fashion. Flawless and continuous tetragonal distortion of such a large amount of bulk-like material is remarkable from both a fundamental and practical perspective.

### Example 2

### Selective Growth of SiGe with H₃SiGeH₃

The blanket growth studies described in Example 1 suggest that highly strained metastable structures are accessible via deposition of silylgermanes. For mobility enhancement applications in simple transistors, these materials must be deposited selectively in the source and drain regions of these device structures. To explore this potential, a brief selective area growth study was pursued using H₃SiGeH₃. In these investigations, test wafers were utilized as provided by ASM America (Phoenix Ariz.), incorporating an array of architectures including simple transistor structures and various patterns masked by amorphous nitride and oxide thin layers. The growth was conducted on ˜1 cm² substrates which were cleaved from an 8″ wafer to fit the dimensions of the deposition stage. The sample preparation and the growth conditions were virtually identical to those employed for the blanket deposition of the compounds in Example 1.

These experiments produced selectively-grown layers with typical thickness comparable to those described in Example 1. In all cases, optical microscopy examinations of the “as deposited” samples revealed that the appearance of the nitride/oxide masked regions of the wafer remained the same while the coloration of the Si-based areas was changed from a metallic grey, typical of Si, to a light brownish hue indicating that selective deposition had occurred.

A comprehensive characterization of all samples was then performed by RBS, Raman, XRD, AFM, XTEM and the data revealed the presence of atomically flat Si—Ge films with single crystalline and partially strained microstructures throughout the samples. The film nominal thickness was estimated by the random RBS and confirmed by XTEM to be in the 45-200 nm range yielding growth rates up to 3 nm per minute depending on the precursors. The channeled RBS spectra of all films indicated that the material was highly aligned and commensurate with the underlying substrate.

The selectivity of growth as well as the local composition and the strain of films grown on the various, discrete device features of the wafer were extensively characterized by micro Raman spectroscopy. In these experiments well-defined masked and unmasked device areas of interest on the wafer surface were studied with a spatial resolution of approximately 1 μm. The spectra of all samples obtained from the nitride/oxide covered features invariably showed only a single peak corresponding to the Si—Si vibrations of the underlying substrate, indicating that no discernable SiGe growth had occurred in these areas at the low growth temperatures employed. However, the spectra obtained from the bare, unmasked Si patterns showed three additional Raman peaks corresponding to the characteristic Si—Si, Si—Ge and Ge—Ge alloy vibrations, indicating significant growth of crystalline Si₁₋ₓGeₓ films directly on the Si surface. The Raman spectra of material with nearly stoichiometric Si_{0.47-48}Ge_{0.53-52} compositions and ˜50 nm thickness showed compressive strains of ˜0.7%. However values as high as 1-1.2% were obtained from XRD RSM measurements. In general the magnitude of the strain seemed to depend on the layer thickness and the growth rate. For example, Raman and XRD of films with RBS compositions and thickness of Si_{0.48}Ge_{0.52} and 180 nm, respectively, grown using SiH₃GeH₃ at a rate of 3 nm/min revealed a significantly low compressive strain of 0.25%. This value increased systematically with decreasing film thickness.

XTEM micrographs of all samples clearly demonstrated that the Si—Ge films deposited conformably on the sidewalls and bottom of the trench portion of typical device structures entirely filling the drain/source region (S/D). Furthermore, the films are atomically flat (AFM roughness of 0.5 nm) which is consistent with a layer-by-layer growth mode.

These preliminary experiments indicated that nearly stoichiometric SiGe can be grown selectively on a routine basis via low temperature depositions of silylgermanes. A key outcome of the latter experiments is that the degree of relaxation in the selectively grown films appears to be related to the lower growth rates obtained thus far relative to those observed in the growth of continuous layers.

The Raman profiles of strain and composition in all samples were derived from individual device features throughout the entire wafer. The corresponding XRD/RBS measurements, however, were obtained from much large areas covering an extensive ensemble of such features. The relatively close match that is found to exist between the composition and strain of the localized devices and those of the bulk-wafer surface further confirms the precise compositional and strain control that can be achieved by selective area deposition of silygermanes.

Collectively the Raman, RBS and XRD analyses indicated that the low temperature depositions have afforded controllable and fairly homogeneous composition and strain profiles within and among individual device architectures. This level of uniformity is critically important for achieving reliable, reproducible and cost effective device fabrication and performance.

### Example 3

### Growth of Continuous and Strained SiGe with HSi(GeH₃)₃ and GeH₃SiH₂SiH₂GeH₃

Growth using the (GeH₃)₃SiH precursor proceeds at 330° C., and the resulting layers analyzed as discussed above; the results are shown in Table 2. Significant metastability effects were observed despite the effective stress driving the relaxation being higher due to the larger lattice mismatch for a 3/1 Ge to Si ratio. The measured strain of up to 2.1% far exceeds the equilibrium values, and can be modeled reasonably well with Houghton's model, albeit with a larger value n₀=4×10⁻² nm⁻². Using analogous precursor-based methodologies, strain values approaching 2.4% in Si_{0.66}Ge_{0.33} layers have been obtained with 22-25 nm thickness produced via deposition of (SiHCl)(GeH₃)₂.

TABLE 2

| Precursor | h (nm) | a(Å) | c(Å) | x^{XRD} | ε_{\|\|}^{XRD} | x^{RBS} | x^{Raman} | ε_{\|\|}^{Raman} |
|---|---|---|---|---|---|---|---|---|
| (GeH₃)₃SiH | 26 | 5.480 | 5.687 | 0.76 | 2.1% | | 0.82 | 2.0% |
| (GeH₃)₃SiH | 28 | 5.521 | 5.658 | 0.76 | 1.4% | 0.79 | 0.82 | 1.4% |
| (GeH₃)₃SiH | 105 | 5.563 | 5.629 | 0.77 | 0.66% | 0.77 | | |
| (GeH₃)₃SiH | 190 | 5.572 | 5.622 | 0.77 | 0.55% | 0.77 | 0.76 | 0.25% |

### Example 4

### Selective Growth of SiGe with HSi(GeH₃)₃

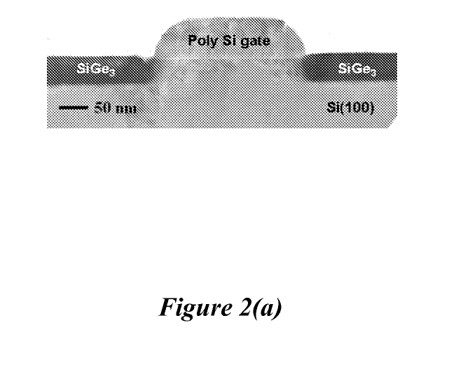

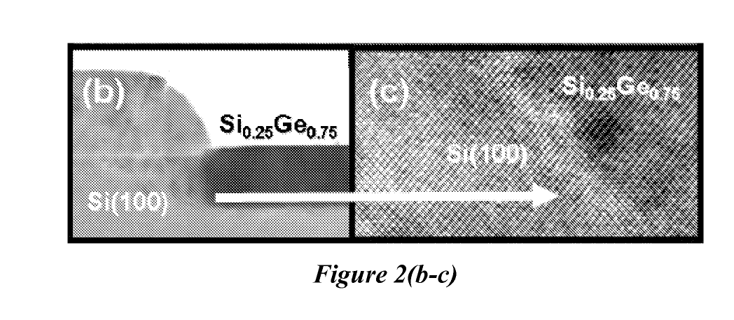

The above findings raise the possibility that selectivity may also be achievable with other Ge-rich silylgermanes within the extended (H₃Ge)ₓSiH₄₋ₓ family of compounds. In addition to the microelectronics applications of the Ge_{0.50}Si_{0.50} alloys produced using SiH₃GeH₃, the selective area growth of Ge_{0.75}Si_{0.25} films potentially derived from the HSi(GeH₃)₃ analog may have significant impact in the emerging and highly sought integration of Si-based optical components such as Ge-rich based photodetectors with conventional microelectronics onto the same chip. Selective deposition of Ge_{0.75}Si_{0.25} materials was explored in the source and drain recess areas of conventional transistors. Growth was conducted using the same procedure employed in the patterned wafer deposition of the Ge_{0.50}Si_{0.50} system in Example 2. The higher reactivity and increased mass of the HSi(GeH₃)₃ compound allows growth to proceed at unprecedented low temperatures in the range 330-350° C. Using this approach, fully relaxed films were formed seamlessly and conformally in the S/D regions of transistors within the test wafer as shown in FIG. 2 (a,b,c). The XTEM micrographs of these samples confirm the selective formation of a 70 nm thick atomically flat Ge_{0.75}Si_{0.25} film devoid of threading dislocations. XRD and Raman corroborated the RBS composition to within a few percent and also indicated that the layer is fully relaxed. The atomic resolution image in FIG. 2 (c) shows a perfectly epitaxial hetero-interface containing a series of clearly visible edge dislocations. These provide the strain relief mechanism to yield relaxed overlayers consistent with XRD/Raman measurements.

### Example 5

### Selective Growth of SiGe with GeH₃SiH₂SiH₂GeH₃

Depositions were conducted at 400-450° C. using the hydride GeH₃SiH₂SiH₂GeH₃ at 350-400° C. via direct insertion of the compound vapor pressure into a gas source MBE chamber. The growth pressure under these conditions was maintained at 5×10⁻⁵ Torr. The “as deposited” samples showed that the appearance of the nitride/oxide masked regions of the wafer was unchanged while the coloration of the Si-based areas was transformed from a metallic grey, typical of Si, to a light brownish hue indicating that selective deposition had occurred.

A comprehensive characterization of the wafers was performed by RBS, Raman, XRD, AFM, XTEM and the data revealed the presence of atomically flat Si—Ge films with single crystalline and partially strained microstructures throughout the samples. The film nominal thickness was estimated by the random RBS spectra and confirmed by XTEM to be in the 45-80 nm range yielding an average growth rates up to ˜3 nm per minute. The channeled spectra indicated that the material was highly aligned and commensurate with the underlying substrate.

The selectivity of growth as well as the local composition and the strain of films grown on the various, discrete device features of the wafer were extensively characterized by micro Raman (1.0 μm resolution). In these experiments the high resolution microscope of the spectrometer was used to identify and select well-defined masked and unmasked device features of interest on the wafer surface to record their Raman spectra. The spectra of all samples obtained from the nitride/oxide covered features invariably showed only a single peak corresponding to the Si—Si vibrations of the underlying substrate indicating that no discernable SiGe growth had occurred in these areas at the low growth temperatures employed. The spectra obtained from the bare, unmasked Si patterns, however, showed an additional three Raman peaks corresponding to the characteristic Si—Si, Si—Ge and Ge—Ge alloy vibrations indicating significant growth of perfectly crystalline Si₁₋ₓGeₓ films directly on the Si surface. The Raman spectra of Si₁₋ₓGeₓ films grown using the GeH₃SiH₂SiH₂GeH₃ yielded a composition of Si_{0.48}Ge_{0.52} on all device structures throughout the wafer. The value is in agreement with RBS measurements and is remarkably close to the SiGe content of the corresponding precursor.

XTEM micrographs of all samples clearly demonstrated that the Si—Ge films deposited conformably on the sidewalls and bottom of the trench portion of typical device structures entirely filling the drain/source region (S/D).

The Raman profiles of strain and composition were derived from individual device features throughout the entire wafer. The corresponding XRD/RBS measurements, however, were obtained from much large areas covering an extensive ensemble of such features. The relatively close match that is found to exist between the composition and strain of the localized devices and those of the bulk-wafer surface further confirms the precise compositional and strain control that can be achieved by selective area deposition of silygermanes. Collectively the Raman, RBS and XRD analyses indicated that the low temperature depositions of all compounds have afforded controllable and fairly homogeneous composition and strain profiles within and among individual device architectures. This level of uniformity is critically important for achieving reliable, reproducible and cost effective device fabrication and performance.

The use of single sources simplifies significantly the integration scheme by circumventing complex multi component reactions and corrosive Cl₂ etchants which are typically necessary to promote selective deposition in conventional processes.

### Example 6

### Modeling of Growth of Continuous and Strained SiGe Alloys

Strain relaxation in epitaxial Si₁₋ₓGeₓ alloys has been shown to be dominated by 60° dislocations with a Burgers vector of magnitude b=a/√2, where a is the cubic lattice constant. The effective stress driving the relaxation can be written as

$${τ}_{eff} = 3.88 [ x - \frac{{ɛ}_{dis}}{{f}_{0}} - \frac{0.55}{d} ln ( \frac{4 d}{b} ) ] GPa \qquad ( 1 )$$

where d is the film thickness, f₀=0.042 the strain mismatch between Si and Ge, and ε_{dis} the strain relaxation produced by the presence of dislocations. For ε_{dis}=0 this expression reduces to that used by Houghton (J. Appl. Phys. 70, 2136-2151 (1991)) to analyze the initial stages of strain relaxation. Setting the square bracket in Eq. (1) equal to zero, we obtain for the equilibrium strain ε:

$$\vert {ɛ}_{p} \vert ; {f}_{0} x - {ɛ}_{dis} = \frac{0.023}{d} ln ( \frac{4 d}{b} ) \qquad ( 2 )$$

The critical thickness d_{c} obtains from Eq. (2) for ε_{dis}=0. Eq. (2) is plotted as a solid line in FIG. 2. The measured strain clearly exceeds this theoretical prediction.

Kinetic relaxation models have been developed to account for strain metastability. These models consider the combined dynamics of misfit dislocations with linear density ρ_{md}, and threading dislocations with areal density n_{td}. The strain relaxation is related to the misfit dislocation density by ε_{dis}=ρ_{md}b cos λ, where λ is the angle between the Burgers vector and the growth plane in a direction perpendicular to the dislocation line. For 60° dislocations ε_{dis}=ρ_{md}b/2. If it is assumed that misfit dislocations are created by lateral bending of threading segments at a velocity ν, the relationship between misfit and threading dislocations is

$$\frac{d {ρ}_{md}}{d t} = v ( t ) {n}_{td} ( t ) \qquad ( 3 )$$

Threading segments are assumed to be created by half-loop nucleation at the free surface at a rate j, and pinned with probability η by interactions with misfit dislocations. This yields the additional equation

$$\frac{d {n}_{td}}{d t} = j - η v ( t ) {n}_{td} ( t ) {ρ}_{md} ( t ) \qquad ( 4 )$$

Houghton (J. Appl. Phys. 70, 2136-2151 (1991); and J. Mater. Sci., Mater. Electr. 6, 280 (1995)) applied this model to the early stages of strain relaxation, defined as ε_{dis}≧10⁻⁵. For this he assumed that the dislocation velocity is given by

$$v = {{v}_{0} ( \frac{{τ}_{eff}}{μ} )}^{m} exp ( \frac{- {Q}_{v}}{{k}_{B} T} ) , \qquad ( 5 )$$

where μ is the shear modulus, k_{B} Boltzmann's constant and T the temperature in K. The constants ν₀, m, and Q_{ν} were fit to experimental data and found to be ν₀=4×10²° nm/s, m=2, and Q_{ν}=2.25 eV. Furthermore, Hougton assumed that the threading dislocation generation rate is given by

$$j = {{Bn}_{0} ( \frac{{τ}_{eff}}{μ} )}^{n} exp ( \frac{- {Q}_{n}}{{k}_{B} T} ) , \qquad ( 6 )$$

where n₀ is the initial density of nucleation sites. The constants B, n, Qₙ were adjusted to experimental data and found to be B=10¹⁸ s⁻¹, n=2.5, and Qₙ=2.5 eV. Using Eq. (5) and (6), Houghton calculated the strain relaxation by solving the coupled system (3) and (4). Since the model is applied to the early stages to strain relaxation, Houghton's used an expression for the effective stress that corresponds to Eq. (1) with E_{dis}=0, and he neglected dislocation pinning.

We have extended Houghton's model to large strain relaxations by using the effective stress in Eq. (1). The probability of dislocation pinning in Eq. (4) was considered by Hull et al. (J. Appl. Phys. 66, 5837-5843 (1989)). They find that pinning plays a significant role in films with d; 30 nm and x H 0.25, but its importance decreases for thicker films and higher Ge concentrations. Thus we continue to neglect the pinning term. Eqs. (3) and (4) are integrated numerically using Eqs. (5) and (6) and setting d′(t)=ν_{growth}. The experimental data are fit by adjusting the parameter n₀.

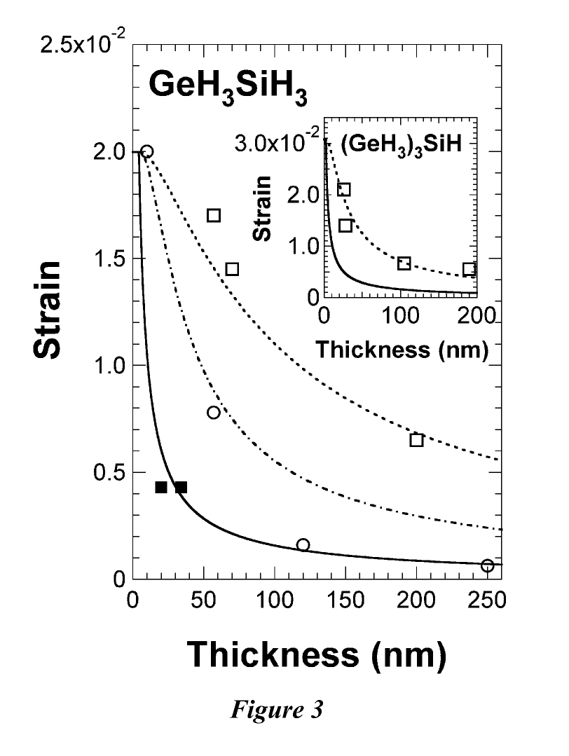

FIG. 3 shows the results for n₀=4×10⁻⁶ nm⁻². This value of n₀ reproduces our data well and also accounts for the strain relaxation observed by Bean et al. in Si₅₀Ge₅₀ films grown by MBE on Si at 550° C. (Bean et al., J. Vac. Sci. Tech. A 2, 436-440 (1984)). The growth rate of the Bean-MBE samples in FIG. 3 was higher than that of our samples. For a given thickness, higher growth rates result in less relaxation. However, the strain relaxation has an activation energy of 4.75 eV, (Houghton, J. Appl. Phys. 70, 2136-2151 (1991)) and is therefore extremely sensitive to the growth temperature. As a result of this strong temperature dependence, the films grown at 430° C. relax much more slowly than those grown at 500° C. A 57 nm thick sample is almost fully strained (˜1.7-2%) while the thickness is almost six times higher than the thickness of a fully strained sample grown by MBE at 500° C., underscoring the large suppression of relaxation effects by decreasing the growth temperature.

We claim:

1. A method for the selective deposition of a Si₁₋ₓGeₓ layer comprising
contacting a substrate having a surface layer comprising at least two portions, wherein a first portion of the surface layer comprises a semiconductor surface layer and a second portion of the surface layer comprises an oxide, nitride, or oxynitride surface layer,
with a gaseous precursor comprising a compound of the molecular formula,
Si_{y}Ge_{z}Hₐ
wherein y is 1, 2, 3, or 4; z is 1, 2, 3, or 4; a is 2(y+z+1); provided that
(i) the sum of y and z is less than or equal to 5; and
(ii) z is greater than or equal to y;
under conditions sufficient to selectively deposit a Si₁₋ₓGeₓ layer, having a predetermined thickness and at a predetermined rate, over only the first portion of the surface, wherein x is greater than about 0.45.

2. The method of claim 1, wherein the Si₁₋ₓGeₓ layer is deposited by gas source molecular beam epitaxy or chemical vapor deposition.

3. The method of claim 1, wherein the gaseous precursor is introduced in substantially pure form.

4. The method of claim 1, wherein the gaseous precursor is introduced as a single gas source.

5. The method of claim 1, wherein the gaseous precursor is introduced intermixed with an inert carrier gas.

6. The method of claim 5, wherein the inert carrier gas comprises H₂.

7. The method of claim 5, wherein the inert carrier gas comprises N₂.

8. The method of claim 1, wherein the contacting takes place at about 300-500° C.

9. The method of claim 1, wherein the contacting takes place at about 1×10⁻³-1×10⁻⁷ ton.

10. The method of claim 1, wherein the predetermined rate is greater than about 2.0 nm/min.

11. The method of claim 10, wherein the predetermined rate is about 2.0-10.0 nm/min.

12. The method of claim 1, wherein the predetermined thickness is about 25-300 nm.

13. The method of claim 1, wherein y is 1 and z is 1, 2, 3, or 4.

14. The method of claim 13, wherein the compound is of the formula, (H₃Ge)_{b}SiH_{4-b}, wherein b is 1, 2, 3, or 4.

15. The method of claim 14, wherein the compound is (H₃Ge)₃SiH.

16. The method of claim 14, wherein the compound is H₃SiGeH₃.

17. The method of claim 1, wherein y is 2 and z is 2 or 3.

18. The method of claim 1, wherein the Si₁₋ₓGeₓ layer is compressively strained.

19. The method of claim 18, wherein the Si₁₋ₓGeₓ layer is fully strained.

20. The method of claim 1, wherein the first portion comprises Si(100) or Si(111).

21. The method of claim 1, wherein the second portion comprises silicon oxide, silicon nitride, silicon oxynitride, or mixtures thereof.

22. The method of claim 1, wherein x is about 0.45-0.95.

23. The method of claim 1, wherein x is about 0.45-0.55.

24. The method of claim 1, wherein x is about 0.70-0.80.

25. The method of claim 1, wherein the surface of the Si₁₋ₓGeₓ layer is atomically flat.

26. The method of claim 1, wherein the surface layer comprises one or a plurality of transistor architectures, each comprising a gate region, a source region, and a drain region, wherein the first portion of the surface layer comprises the source regions and the drain regions and the second portion of the surface layer comprises the gate region.

27. The method of claim 26, wherein the gate regions comprise a polysilicon gate having an oxide, nitride, or oxynitride hardmask.

28. A method for growing a fully compressively strained SiₓGe₁₋ₓ layer on a substrate comprising,
contacting a semiconductor substrate with a gaseous precursor comprising a compound of the molecular formula,
Si_{y}Ge_{z}Hₐ
wherein y is 1, 2, 3, or 4; z is 1, 2, 3, or 4; a is 2(y+z+1); provided that
(iii) the sum of y and z is less than or equal to 5; and
(iv) z is greater than or equal to y;
under conditions sufficient to deposit a fully compressively strained Si₁₋ₓGeₓ layer, having a thickness, at a predetermined rate, wherein x is greater than about 0.45.

29. The method of claim 28, wherein the thickness of the fully compressively strained Si₁₋ₓGeₓ layer is greater than the equilibrium critical thickness.

30. The method of claim 29, wherein the thickness is greater than about 2 nm.

31. The method of claim 28, wherein y equals z.

32. The method of claim 28, wherein the compound is H₃SiGeH₃ or HSi(GeH₃)₃.

33. The method of claim 28, wherein the substrate comprises Si(100).

34. The method of claim 28, wherein the contacting occurs at a temperature ranging from about 300 to about 450° C.

35. The method of claim 28, wherein the predetermined rate is greater than about 2 nm/min.

36. The method of claim 35, wherein the predetermined rate is about 2 to about 10 nm/min.

37. The method of claim 28, wherein the fully compressively strained Si₁₋ₓGeₓ layer has an essentially uniform tetragonal structure.

38. The method of claim 28, wherein the fully compressively strained Si₁₋ₓGeₓ layer has lattice constants of about a=5.428 Å and c=5.595 Å.

39. The method of claim 28, wherein the substrate comprised a surface layer comprising at least two portions, wherein a first portion of the surface layer comprises a semiconductor surface layer and a second portion of the surface layer comprises an oxide, nitride, or oxynitride surface layer, and the fully compressively strained Si₁₋ₓGeₓ layer is formed only over the first portion of the surface layer.

40. The method of claim 28, wherein the compound is H₃SiGeH₃, x is about 0.50, and the thickness is about 60 nm.

41. The method of claim 28, wherein the compound is HSi(GeH₃)₃, x is about 0.75, and the thickness is about 30 nm.
